(19) United States
(12) Patent Application Publication
(10) Pub. No.: US 2018/0304826 A1
(43) Pub. Date: Oct. 25, 2018

(54) NOISE FILTER OF VEHICLE-MOUNTED DEVICE AND VEHICLE-MOUNTED DEVICE

(71) Applicant: HITACHI AUTOMOTIVE SYSTEMS, LTD., Hitachinaka-shi, Ibaraki (JP)

(72) Inventors: Yasuo YAHAGI, Tokyo (JP); Mikihiro KAJIURA, Hitachinaka-shi (JP); Akinori SUZUKI, Hitachinaka-shi (JP)

(73) Assignee: HITACHI AUTOMOTIVE SYSTEMS, LTD., Hitachinaka-shi, Ibaraki (JP)

(21) Appl. No.: 15/738,021

(22) PCT Filed: Mar. 15, 2016
(86) PCT No.: PCT/JP2016/058081

§ 371 Date: Dec. 19, 2017

(30) Foreign Application Priority Data
Sep. 24, 2015 (JP) 2015-186935

(51) Int. Cl. B60R 16/02; H01F 17/06; H01F 27/06; H01F 27/29; H03H 7/01; H01F 37/00

(52) U.S. Cl. CPC B60R 16/02; H01F 17/06; H01F 37/00; H01F 27/29; H03H 7/01; H01F 27/06

(57) ABSTRACT

A noise filter of a vehicle-mounted device includes: a support device provided on a casing of the vehicle-mounted device; a magnetic body supported by the support device; and a coil having a winding portion wound around the magnetic body. The support device supports the magnetic body such that an outer peripheral side surface of the winding portion is situated at a position spaced away from the casing.

### TECHNICAL FIELD

The present invention relates to a noise filter of a vehicle-mounted device and a vehicle-mounted device.

### BACKGROUND ART

Conventionally, a noise filter has been known in which a coil constituting a noise filter is fixed in position by molding resin (See paragraphs [0002] and [0012] of the specification of Patent Document 1).

### PRIOR ART DOCUMENT

### Patent Document

Patent Document 1: JP-2002-280235-A

### SUMMARY OF THE INVENTION

### Problem to be Solved by the Invention

The present inventors have found out a problem in the prior art that covering a coil constituting a noise filter with molding resin results in deterioration in electrical characteristics.

### Means for Solving the Problem

According to a mode of the present invention, there is provided a noise filter of a vehicle-mounted device, including: a support device provided on a casing of the vehicle-mounted device; a magnetic body supported by the support device; and a coil having a winding portion wound around the magnetic body. The support device supports the magnetic body such that an outer peripheral side surface of the winding portion is situated at a position spaced away from the casing.

### Effect of the Invention

According to the present invention, it is possible to fix a noise filter to a vehicle-mounted device without involving deterioration in electrical characteristics.

### BRIEF DESCRIPTION OF THE DRAWINGS

FIG. 1 is a schematic longitudinal sectional view of a valve timing control device constituting an example of a vehicle-mounted device.

FIG. 2 is an exploded perspective view of the valve timing control device.

FIG. 3 is a diagram illustrating a cover member as seen from the front side of the valve timing control device.

FIG. 4 is a circuit diagram illustrating the construction of a noise filter.

FIG. 5(a) is a schematic side view of a retaining structure for an inductor according to a first embodiment, FIG. 5(b) is a schematic sectional view taken along line vb-vb of FIG. 5(a), and FIG. 5(c) is a schematic diagram illustrating a support portion of FIG. 5(b).

FIG. 6 is a chart illustrating impedance frequency characteristics.

FIG. 7(a) is a schematic side view of a retaining structure for an inductor according to a second embodiment, FIG. 7(b) is a schematic sectional view taken along line viib-viib of FIG. 7(a), FIG. 7(c) is a diagram illustrating the support portion of FIG. 7(b) as seen from the side opposite that of FIG. 7(b).

FIG. 8(a) is a schematic side view of a retaining structure for an inductor according to a third embodiment, and FIG. 8(b) is a schematic sectional view taken along line viiib-viiib of FIG. 8(a).

FIG. 9(a) is a schematic side view of a retaining structure for an inductor according to modification 1, and FIG. 9(b) is a schematic side view of a retaining structure for an inductor according to modification 2.

FIG. 10 is a schematic side view of a retaining structure for an inductor (a toroidal type coil) according to modification 5.

### MODES FOR CARRYING OUT THE INVENTION

In the following, a vehicle-mounted device according to an embodiment of the present invention will be described with reference to the drawings.

### First Embodiment

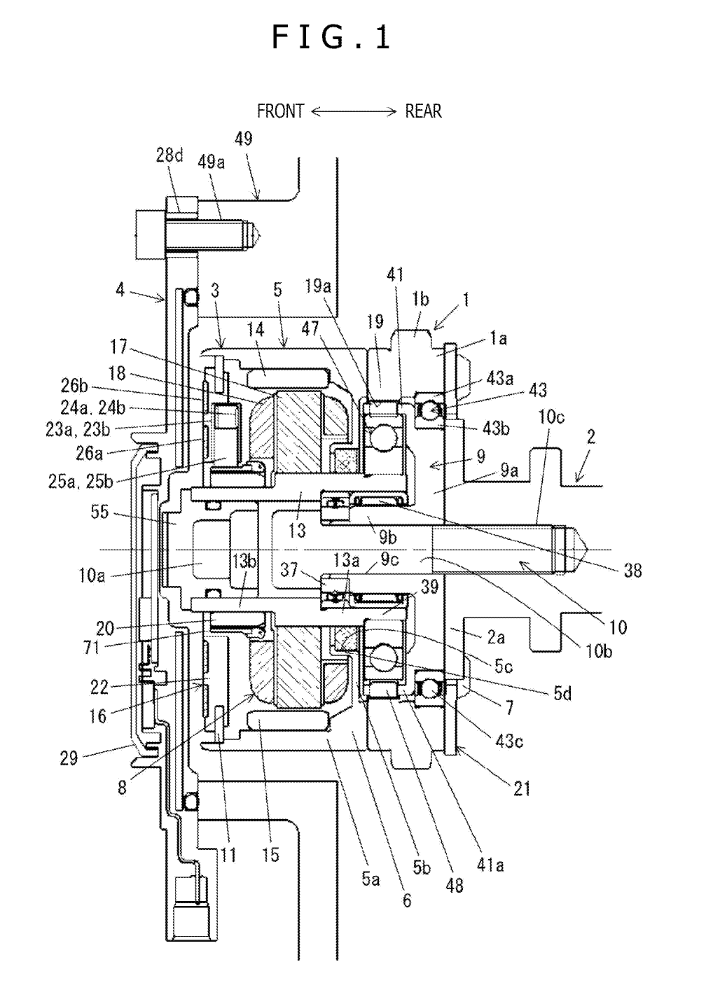

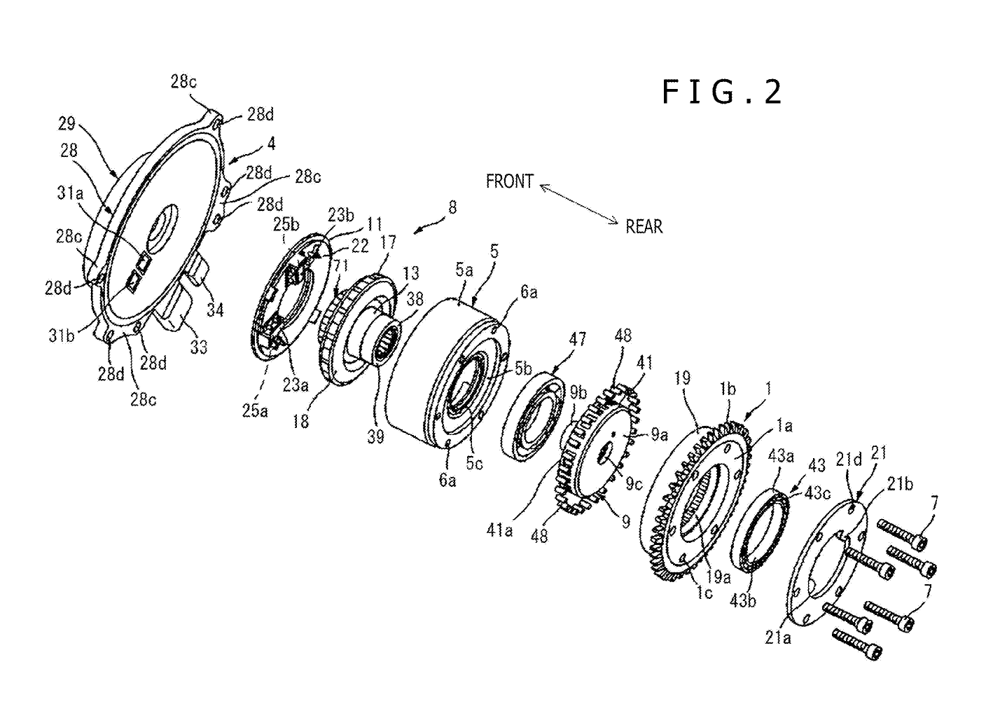

FIG. 1 is a schematic longitudinal sectional view of a valve timing control device constituting an example of a vehicle-mounted device which is an engine (internal combustion engine), and FIG. 2 is an exploded perspective view of the valve timing control device. For the sake of convenience in description, the front-rear direction of the valve timing control device is determined as shown in the drawings. The valve timing control device is a device for varying the opening/closing timing of the engine valve at will to control the combustion chamber charge amount such that a combustion state suitable for the engine speed and the load is attained in order to achieve an improvement in terms of the fuel efficiency of the automobile and to reduce the carbon dioxide emission amount.

As shown in FIGS. 1 and 2, the valve timing control device is equipped with a timing sprocket 1 which is a drive rotary body configured to be driven to rotate by the crankshaft of the engine (internal combustion engine), a cam shaft 2 rotatably supported on a cylinder head (not shown) via a bearing (not shown) and configured to be rotated by a rotational force transmitted from the timing sprocket 1, a cover member 4 fixed to a chain cover 49 arranged at a position in front of the timing sprocket 1, and a phase change mechanism 3 changing the relative rotation phase of the timing sprocket 1 and the cam shaft 2 in accordance with the engine operating condition.

The timing sprocket 1 as a whole is formed of an iron type metal in an integral annular configuration and is composed of a sprocket main body 1a the inner peripheral surface of which is of a step-like configuration, a gear portion 1b integrally provided in the outer periphery of the sprocket main body 1a and receiving a rotational force from the crankshaft via a timing chain (not shown) wound around it, and an inner teeth forming portion 19 provided integrally at the front end side of the sprocket main body 1a.

Between a driven member 9 described below provided at the front end portion of the cam shaft 2 and the sprocket main body 1a, there is provided a large diameter ball bearing 43. The timing sprocket 1 and the cam shaft 2 are supported by the large diameter ball bearing 43 so as to allow relative rotation.

The large diameter ball bearing 43 is composed of an outer ring 43a, an inner ring 43b, and balls 43c provided between the outer ring 43a and the inner ring 43b. The outer ring 43a of the large diameter ball bearing 43 is fixed to the inner peripheral side of the sprocket main body 1a, and the inner ring 43b thereof is fixed to the outer peripheral side of the driven member 9.

The inner teeth forming portion 19 is provided integrally with the front end portion of the sprocket main body 1a, and is formed as a cylinder extending to the front side. In the inner periphery of the inner teeth forming portion 19, there are formed a plurality of wave-shaped inner teeth 19a. At the front end side of the inner teeth forming portion 19, there is arranged opposite the inner teeth forming portion 19 an annular female screw forming portion 6 provided in a motor housing 5 described below.

At the rear end portion on the side opposite the inner teeth forming portion 19 of the sprocket main body 1a, there is arranged an annular retaining plate 21. The retaining plate 21 is formed integrally of a metal plate material. As shown in FIG. 1, the outer diameter of the retaining plate 21 is set to the same as that of the sprocket main body 1a, and the inner diameter thereof is set to a diameter smaller than the inner diameter of the outer ring 43a of the large diameter ball bearing 43. The inner peripheral portion 21a of the retaining plate 21 is arranged so as to abut the outer end surface in the axial direction of the outer ring 43a. As shown in FIG. 2, at a predetermined position of the inner peripheral edge of the inner peripheral portion 21a, there is integrally provided a stopper protrusion 21b protruding to the inner side in the radial direction, that is, toward the center axis.

In the outer peripheral portion of the retaining plate 21, there are formed, at equal peripheral intervals and so as to extend through the retaining plate, six bolt insertion holes 21d through which six bolts 7 are passed.

In the respective outer peripheral portions of the sprocket main body 1a (inner teeth forming portion 19) and the retaining plate 21, there are respectively formed six bolt insertion holes 1c and six bolt insertion holes 21d at substantially equal peripheral intervals and so as to extend through them. The female screw forming portion 6 has six female screw holes 6a formed at positions corresponding to the bolt insertion holes 1c and 21d. The six bolts 7 are inserted into the bolt insertion holes 1c and 21d and threadedly engaged with the female screw holes 6a, whereby the timing sprocket 1, the retaining plate 21, and the motor housing 5 are fastened together and fixed in position in the axial direction.

The cover member 4 is formed of resin material, and is arranged so as to cover the front end portion of the motor housing 5. The cover member 4 is equipped with a base 28 on which an electronic board and the like equipped with a noise filter described below, a rotational angle sensor for an electric motor 8, etc. are mounted at high density, a covering member 29 protecting the members such as the electronic board and the like arranged on the front side of the base 28, and connector portions 33 and 34 for connecting the valve timing control device to an engine controller performing the control and the like of the valve timing control device. A flange 28c is formed at the outer peripheral edge of the base 28. The flange 28c is provided with a plurality of boss portions 28d arranged at unequal circumferential intervals. As shown in FIG. 1, the bolts are passed through the boss portions 28d and are threadedly engaged with the female screw holes 49a of the chain cover 49, whereby the cover member 4 is fixed to the chain cover 49.

The motor housing 5 is equipped with a cylindrical housing main body 5a formed as a bottomed cylinder through pressing of an iron type metal material, and a sealing plate 11 formed of a non-magnetic resin material sealing the front end opening of the housing main body 5a.

The housing main body 5a has a disk-like partition wall 5b at the rear end side. At substantially the center of the partition wall 5b, there is formed a shaft portion insertion hole 5c through which an eccentric shaft portion 39 described below is passed. At the hole edge of the shaft portion insertion hole 5c, there is provided a cylindrical extension portion 5d protruding parallel to the axial direction of the cam shaft 2. The female screw forming portion 6 is provided on the outer peripheral side of the front end surface of the partition wall 5b.

As shown in FIG. 1, in its outer periphery, the cam shaft has two drive cams (not shown) per cylinder for opening operation of an intake valve (not shown). At the front end portion of the cam shaft 2, a flange 2a is integrally provided. The outer diameter of the flange 2a is set to be slightly larger than the outer diameter of a fixed end portion 9a of a driven member 9 described below, and, after the assembly of the components, the outer peripheral portion of the front end surface thereof is arranged so as to abut the outer end surface, in the axial direction, of the inner ring 43b of the large diameter ball bearing 43. The cam shaft 2 and the driven member 9 are connected together in the axial direction by a cam bolt 10, with the front end surface of the flange 2a abutting the driven member 9 from the axial direction.

As shown in FIG. 1, a head portion 10a of the cam bolt 10 supports the inner ring of a roller bearing 37 from the axial direction. In the outer periphery of a shaft portion 10b of the cam bolt 10, there is formed a male screw 10c configured to be threadedly engaged with a female screw formed from the end portion of the cam shaft 2 toward the inner side in the axial direction.

The driven member 9 is formed integrally of an iron type metal material. The driven member 9 is equipped with a disk-like fixed end portion 9a formed at the rear end side (cam shaft 2 side), a cylindrical portion 9b protruding in the axial direction from the inner peripheral front end surface of the fixed end portion 9a, and a cylindrical retainer 41 formed integrally with the outer peripheral portion of the fixed end portion 9a and retaining a plurality of rollers 48. The driven member 9 is provided with a through-hole 9c through which the shaft portion 10b of the cam bolt 10 is passed.

The rear end surface of the fixed end portion 9a is arranged so as to abut the front end surface of the flange 2a of the cam shaft 2, and is fixed to the flange 2a by press contact from the axial direction by the axial force of the cam bolt 10. At its center, the cylindrical portion 9b has an insertion hole 9d which extends therethrough and through which the shaft portion 10b of the cam bolt 10 is passed. At the same time, on the outer peripheral side thereof, there is provided a needle bearing 38 which is a bearing member.

As shown in FIGS. 1 and 2, at positions in substantially equal peripheral intervals of a tubular distal end portion 41a of the retainer 41, there are formed a plurality of substantially rectangular roller retaining holes retaining a plurality of rollers 48 so as to allow them to roll. The number of the roller retaining holes (i.e., the number of the rollers 48) is less than the total number of teeth of the inner teeth 19a of the inner teeth forming portion 19 by one.

The phase change mechanism 3 includes the electric motor (direct current (DC) motor with a brush) 8 arranged at the front end side of the cylindrical portion 9b of the driven member 9, and a speed reduction mechanism decreasing the rotational speed of the electric motor 8 and transmitting the decreased rotational speed to the cam shaft 2. The speed reduction mechanism includes the eccentric shaft portion 39 performing an eccentric rotating motion, a medium diameter ball bearing 47 provided in the outer periphery of the eccentric shaft portion 39, the rollers 48 provided in the outer periphery of the medium diameter ball bearing 47, the retainer 41 allowing the rollers 48 to move in the radial direction while retaining them in the rolling direction, and the driven member 9 integral with the retainer 41.

As shown in FIGS. 1 and 2, the electric motor 8 is a DC motor with brush, and is equipped with the motor housing 5 which is a yoke rotating integrally with the timing sprocket 1, a motor output shaft 13 rotatably provided inside the motor housing 5, a pair of semi-arcuate permanent magnets 14 and 15 which are stators fixed to the inner peripheral surface of the motor housing 5, and a stator 16 fixed to the sealing plate 11.

As shown in FIG. 1, the motor output shaft 13 is formed in a stepped cylindrical configuration and functions as an armature. The motor output shaft 13 is composed of a large diameter portion 13a on the rear side and a small diameter portion 13b on the front side. A core rotor 17 is fixed to the outer periphery of the large diameter portion 13a. At the rear end side of the large diameter portion 13a, there is integrally formed the eccentric shaft portion 39 constituting a part of the speed reduction mechanism.

An annular member 20 is forced onto and fixed to the outer periphery of the small diameter portion 13b. A commutator 71 is forced onto and fixed to the outer peripheral surface of the annular member 20 from the axial direction. A plug member 55 suppressing leakage to the exterior of lubricant supplied to the motor output shaft 13 and to the interior of the eccentric shaft portion 39 to lubricate the roller bearing 37 and the needle bearing 38 is forced onto and fixed to the inner peripheral surface of the small diameter portion 13b.

The core rotor 17 is formed of a magnetic material having a plurality of magnetic poles, and the outer peripheral side thereof is formed as a bobbin having a slot for winding the winding of a coil 18. The commutator 71 is formed of a conductive material in an annular configuration. The commutator 71 has segments of the same number as that of poles of the core rotor 17, with the terminal of the led out winding of the coil 18 being electrically connected to each segment.

As shown in FIG. 1, as a whole, the permanent magnets 14 and 15 are formed in a cylindrical configuration, and have a plurality of magnetic poles in the circumferential direction. The position of the permanent magnets 14 and 15 in the axial direction is arranged so as to be offset to the front side of the fixing position of the core rotor 17. That is, the center in the axial direction of the permanent magnets 14 and 15 is arranged so as to be offset to the stator 16 side with respect to the center in the axial direction of the core rotor 17. As a result, the front end portions of the permanent magnets 14 and are arranged so as to overlap the commutator 71, motor brushes 25a and 25b of the stator 16, etc. in the radial direction.

The stator 16 is equipped with a resin plate 22, a pair of resin holders 23a and 23b, a pair of motor brushes 25a and 25b, a first feeder slip ring 26a, and a second feeder slip ring 26b.

The resin plate 22 is a disk-like member formed of a resin material, and is provided integrally on the inner peripheral side of the sealing plate 11. The pair of resin holders 23a and 23b is an accommodating portion accommodating the pair of motor brushes 25a and 25b and is provided on the inner side of the resin plate 22. Inside the resin holders 23a and 23b, there are arranged coil springs 24a and 24b so as to be slidable along the radial direction.

The motor brushes 25a and 25b are pressed toward the outer peripheral surface of the commutator 71 by the spring force (elastic force) of the coil springs 24a and 24b, and abut the commutator 71.

The first feeder slip ring 26a and the second feeder slip ring 26b are embedded and fixed in an exposed state on the front end surface side of the resin plate 22. The first feeder slip ring 26a is of a smaller diameter than the second feeder slip ring 26b, and is arranged on the inner side of the second feeder slip ring 26b. By the first feeder slip ring 26a and the second feeder slip ring 26b, an inner and outer double annular structure is formed. The motor brushes 25a and 25b are electrically connected to the first feeder slip ring 26a and the second feeder slip ring 26b by a harness.

The sealing plate 11 is fixed in position by swaging at the recessed step portion formed in the inner periphery of the front end portion of the motor housing 5.

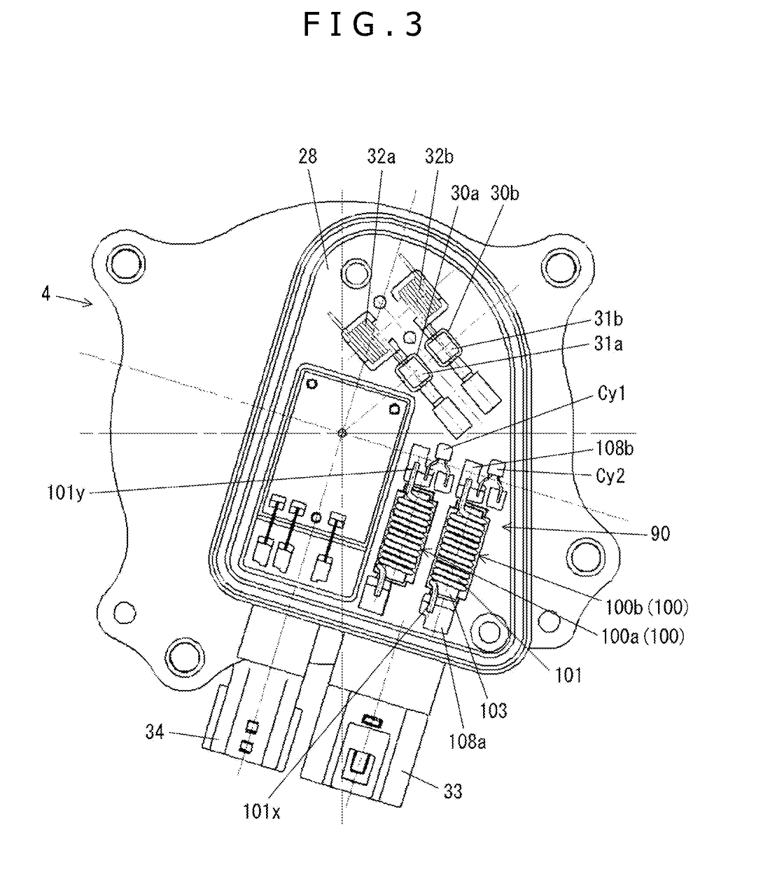

FIG. 3 is a diagram illustrating the cover member 4 as seen from the front side of the valve timing control device. In the base 28 of the cover member 4, there are provided rectangular openings 30a and 30b accommodating a pair of feeder brushes 31a and 31b. The pair of feeder brushes 31a and 31b is electrically connected to a terminal (not shown) of a connector portion 33 via a pair of feeder leads. The terminal of the connector portion 33 is connected to an engine control unit via a harness or the like.

The pair of feeder brushes 31a and 31b are formed as rectangular parallelepipeds extending substantially in the horizontal direction (the axial direction of the electric motor 8), and are retained inside the openings 30a and 30b of the base 28 so as to be slidable in the axial direction of the electric motor 8. The pair of feeder brushes 31a and 31b respectively abut the first feeder slip ring 26a and the second feeder slip ring 26b (See FIG. 1) from the axial direction. The pair of feeder brushes 31a and 31b constitute a part of a feeder mechanism together with the pair of feeder slip rings 26a and 26b.

As shown in FIG. 3, the feeder brushes 31a and 31b are urged toward the slip rings 26a and 26b (See FIG. 1) by the spring force (elastic force) of a pair of torsion springs 32a and 32b arranged on the base 28. As a result, the feeder brushes 31a and 31b abut the slip rings 26a and 26b.

In order to suppress electromagnetic noise emission generated between the slip rings 26a and 26b and the feeder brushes 31a and 31b at the time of switching of the commutator of the electric motor 8, the valve timing control device according to the present embodiment is equipped with a noise filter 90 having inductors 100a and 100b which are dielectric elements and capacitors Cy1 and Cy2 which are capacitance elements.

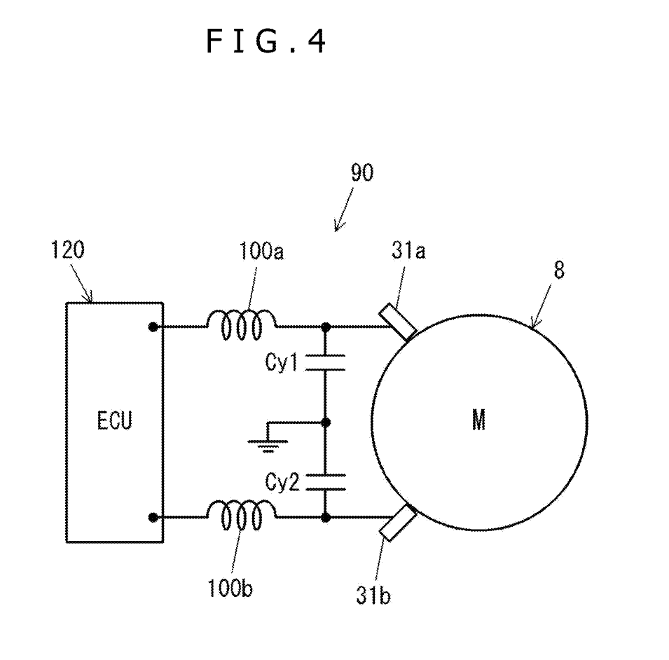

FIG. 4 is a circuit diagram illustrating the construction of the noise filter 90. As shown in FIG. 4, the noise filter 90 is provided between the electric motor 8 and the engine control unit 120. The noise filter 90 is equipped with the inductors 100a and 100b provided in the DC power lines connecting the engine control unit 120 and the electric motor 8, and a Y capacitor. The Y capacitor is composed of the two capacitors Cy1 and Cy2 connecting the grounding terminal and the DC power lines.

The main body of the valve timing control device of the engine (internal combustion engine) is directly installed on the engine, so that it is subject to violent vibration. Thus, the noise filter 90 needs to be firmly fixed to the casing constituting the main body of the valve timing control device.

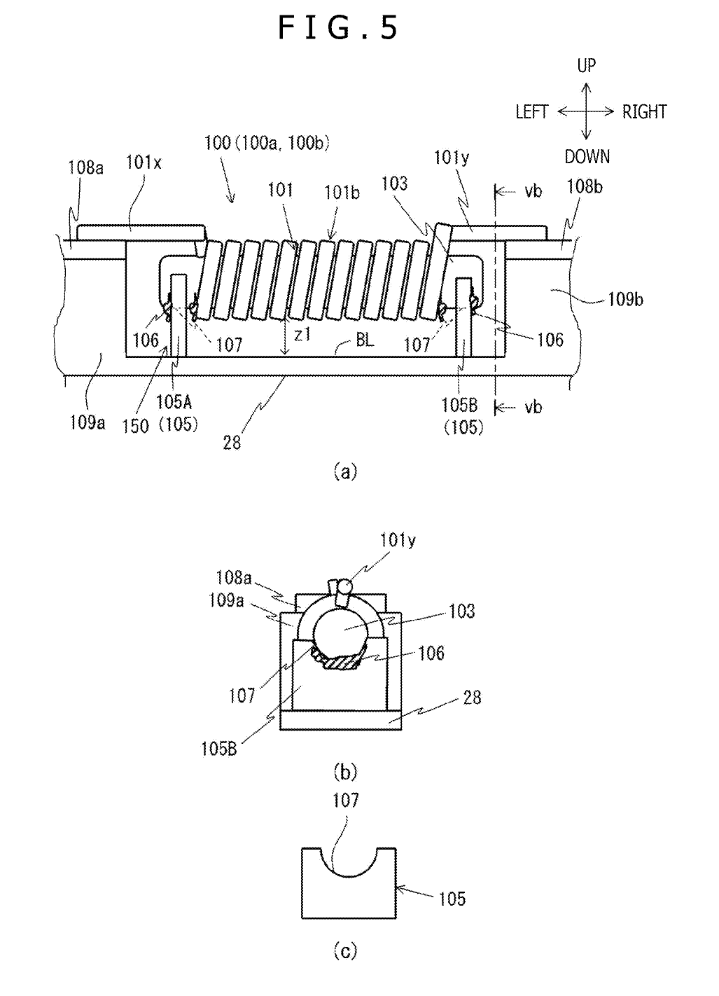

FIG. 5(a) is a schematic side view illustrating the retaining structure for the inductors 100a and 100b according to the first embodiment, FIG. 5(b) is a schematic sectional view taken along line vb-vb of FIG. 5(a). FIG. 5(c) is a schematic diagram illustrating a support portion 105 of FIG. 5(b). The construction of the inductors 100a and 100b and the retaining structure for the same are similar to each other, so that, in the following, both will be generally referred to as the inductors 100, and solely one of the pair of inductors 100 will be described. Further, for the sake of convenience in description, the upper, lower, left, and right sides of the inductors 100 will be defined as illustrated in the drawings.

As shown in FIGS. 3 and 5, in the present embodiment, the inductor 100 is a solenoid, and has a coil 101, and a linear bar-like (columnar in the present embodiment) magnetic body 103 arranged within the coil 101. The coil 101 is a solenoid type coil formed by spirally winding a conductor line around the magnetic body 103. The surface of the conductor line is covered with a thin insulation layer (not shown).

At both end portions of the conductor line constituting the coil 101, there are provided linear leader lines 101x and 101y. The leader line 101x is welded to a bus bar 108a which is a flat-plate-like conductive member, and the leader line 101y is welded to a bus bar 108b which is a flat-plate-like conductive member. As a result, the coil 101 is mechanically fixed to and electrically connected to each of the bus bar 108a and the bus bar 108b. The bus bars 108a and 108b are respectively fixed to bus bar support bases 109a and 109b integrally provided on the base 28 of the cover member 4 by insert molding. The bus bar support bases 109a and 109b and the base 28 may be prepared as separate members and connected to each other by screws or the like.

As shown in FIG. 5, the base 28 of the cover member 4 is provided with a support device 150 supporting both end portions of the inductor (solenoid) 100. The support device 150 is equipped with a pair of support portions 105A and 105B, and the pair of support portions 105A and 105B are provided integrally with the base 28 through resin molding. The support portions 105A and 105B and the base 28 may be prepared as separate members, and connected to each other by screws or the like. Each of the pair of support portions 105A and 105B is formed as a rectangular plate, and each of the pair of support portions 105A and 105B has a curved surface 107 (See FIG. 5(c)) abutting the outer peripheral side surface of the magnetic body 103. The curved surface 107 is formed in an arcuate configuration in its sectional configuration perpendicular to the center axis of the columnar magnetic body 103, and is fit-engaged with the outer peripheral surface of the magnetic body 103. The magnetic body 103 is supported by the pair of support portions 105A and 105B in a center-crank-like fashion, with both end portions thereof being fit-engaged with the curved surface 107. The support portion 105 is in contact solely with the magnetic body 103 of the inductor (solenoid) 100, and is not in contact with the coil 101. The support portions 105A and 105B are of the same construction. Thus, in the following, they will also be generally referred to as the support portions 105.

As shown in the drawing, assuming that the surface of the base 28 is a reference surface BL, the support portions 105 protrude upwardly from the reference surface BL of the base 28. The magnetic body 103 supported by the support portions 105 and the coil 101 wound around the magnetic body 103 are arranged so as to be spaced away from the reference surface BL. In the present embodiment, the portion, of the conductor line constituting the coil 101, wound around the magnetic body 103 (hereinafter referred to as the winding portion 101b) is maintained in a state in which it is spaced away from the base by a predetermined distance, whereby variation in the electrical characteristics of the coil 101 is suppressed. The winding portion 101b is arranged between the pair of support portions 105.

The distance z1 between the surface, of the outer peripheral side surface of the cylindrical winding portion 101b, opposite the reference surface BL of the base 28 (i.e., the lower end surface) and the reference surface BL (i.e., the minimum distance between the winding portion 101b and the base 28) is larger than 0 mm. The distance z1 is determined such that the variation in the electrical characteristics in the coil 101 described below is diminished. It is desirable for the distance to be set to be larger than, for example, the diameter of the conductor line.

Between the curved surface 107 of the support portion 105 and the outer peripheral side surface of the magnetic body 103, there exists an adhesive 106 (e.g., an epoxy type adhesive), and the magnetic body 103 is bonded to the support portion 105. The adhesive 106 is applied to both end portions of the winding portion 101b, and both end portions of the winding portion 101b is bonded to the magnetic body 103 by the adhesive 106. Here, no adhesive exists between adjacent turns of the conductor line constituting the winding portion 101b. Regarding the kind of adhesive 106, it is desirable to select one little affecting the magnetism of the magnetic body 103 (e.g., an epoxy type adhesive). The relative permeability of an epoxy type adhesive is substantially equal to 1, and does not affect the magnetism of the magnetic body 103.

The assembly order of the inductor 100 will be described. Prior to the assembly, the conductor line is wound around the magnetic body 103 to prepare the inductor 100. Both end portions of the winding portion 101b of the coil 101 and the magnetic body 103 are bonded to each other by the adhesive 106.
(i) The adhesive 106 is applied to the curved surfaces 107 of the pair of support portions 105A and 105B.
(ii) Both end portions of the magnetic body 103 to which the coil 101 has been attached is arranged on the curved surfaces 107 of the pair of support portions 105A and 105B.
(iii) The leader line 101x and the leader line 101y provided at both ends of the conductor line constituting the coil 101 are respectively welded to the bus bar 108a and the bus bar 108b.

Of the total mass of the inductor (solenoid) 100, the proportion of the mass of the magnetic body 103 is larger than that of the other components. Thus, when vibration is applied to the valve timing control device, the magnetic body 103 is more subject to displacement than the other components. Thus, to firmly fix the inductor (solenoid) 100, it is effective to directly fix the magnetic body 103.

As described above, in the present embodiment, both end portions of the magnetic body 103 are fit-engaged with the pair of support portions 105 to fix the magnetic body 103 in position by the pair of support portions 105. Further, both end portions of the coil 101 spirally wound around the magnetic body 103 are welded to the bus bars 108a and 108b, whereby the magnetic body 103 is fixed to the bus bar support bases 109a and 109b via the coil 101. Further, both ends of the winding portion 101b and the magnetic body 103 are bonded to each other by the adhesive 106, and the support portions 105 and the magnetic body 103 are bonded to each other by the adhesive 106, whereby the fixation force between the coil 101 and the magnetic body 103 and the fixation force between the magnetic body 103 and the support portions 105 are increased. As a result, the inductor 100 is firmly fixed to the base 28.

The above-described embodiment provides the following effect:
(1) The inductor 100 constituting the noise filter is equipped with the support device 150 provided on the cover member 4 constituting the casing of the electric valve timing control device, the magnetic body 103 supported by the support device 150, and the coil 101 having the winding portion 101b wound around the magnetic body 103. The pair of support portions 105 constituting the support device 150 supports the magnetic body 103 such that the outer peripheral side surface of the winding portion 101b is arranged at a position spaced away from the cover member 4.

As a result, it is possible to fix the inductor 100 constituting the noise filter to the vehicle-mounted device (valve timing control device) without deteriorating the electrical characteristics of the inductor 100 such as the self-resonance frequency and impedance.

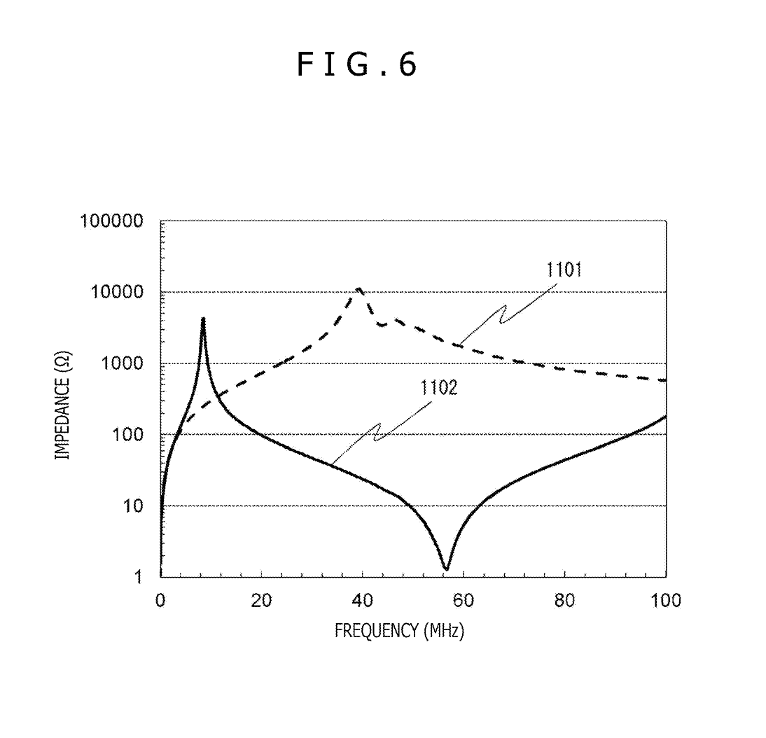

In the following, the effect of the present embodiment will be described specifically by comparing it with a comparative example in which the inductor 100 is resin-molded. FIG. 6 is a diagram illustrating the frequency characteristic of impedance. The solid line indicates the frequency characteristic curve 1102 of an inductor according to a comparative example in which the inductor is fixed in position by resin-molding using epoxy resin. The broken line indicates the frequency characteristic curve 1101 of the inductor 100 according to the present embodiment in which the inductor is not resin-molded.

The frequency characteristic shown in FIG. 6 is the frequency characteristic of an inductor which, by way of example, consists of nickel-zinc (Ni—Zn) ferrite and which is formed by winding an enamel wire of a diameter of 1 mm (2UEW1.0) 15.5 turns around the columnar magnetic body 103 having a diameter of 7 mm and a length of 20 mm.

The frequency characteristic curve 1101 of the inductor 100 according to the present embodiment exhibits an upwardly protruding peak (self-resonance frequency) around a frequency of 40 MHz, and an impedance of several 100Ω at approximately 10 MHz or more. In contrast, the frequency characteristic curve 1102 of the inductor according to the comparative example exhibits an upwardly protruding peak around 10 MHz and a downwardly protruding peak around 56 MHz, and the impedance of approximately 20 MHz to 90 MHz is below 100Ω. That is, in the comparative example in which resin molding is effected, the self-resonance frequency is reduced by approximately 40% as compared with the case where no resin molding is effected (the present embodiment), and the impedance is lowered over a wide frequency band (20 MHz to 90 MHz). Thus, when the inductor according to the comparative example is utilized as a noise filter, the filter characteristic undergoes fluctuation before and after the mold, so that it is impossible to achieve the design specifications of the proper electrical properties of the noise filter. That is, there is a fear of the noise to be removed failing to be suppressed.

The inductors of the present embodiment and the comparative example have a winding structure. Thus, apart from the inductance component (dielectric component) and the resistance component with which the conductor line is endowed, there is parasitically generated a capacitance component. Molding the coil 101 with resin means a change in the inter-line stray capacitance (parasitic capacitance) due to the resin getting between the adjacent turns of the conductor line constituting the winding portion 101b. Thus, as shown in FIG. 6, the present embodiment with no resin molding and the comparative example subjected to resin molding differ from each other in electrical characteristics such as the self-resonance frequency of the inductor and the impedance. In the present embodiment, no molding resin gets between the adjacent turns of the conductor line of the winding portion 101b of the coil 101, so that it is possible to prevent the electrical characteristics of the inductor from being changed from the original characteristics.

Patent Document 1 discloses a structure in which, instead of fixing the coil with molding resin, the coil is fixed in a pressed state by an insulating fixing member mounted to the casing. In the structure in which the winding portion of the coil is mechanically and directly pressed, there is a fear of the insulation layer being damaged to generate short-circuiting due to the friction between the insulating layer of the coil (insulating film) and the fixation member (pressing member) when vibration or a shock is applied to the inductor.

The present embodiment adopts not a structure in which the winding portion 101b is fixed by directly pressing the outer peripheral side surface thereof but a structure in which the magnetic body 103 is supported in a center-crank-like fashion by a pair of support portions 105, with the winding portions 101b being situated at a position spaced away from the base 28. Thus, it is possible to prevent the short-circuiting attributable to damage of the insulation layer (insulating film) of the coil 101 in the structure in which the winding portion 101b is directly pressed.

Further, in the case where the winding portion 101b is fixed by directly pressing the outer peripheral side surface thereof, based on the same concept as in the case where fixation is effected by molding resin as described above, there is a fear of the parasitic capacitance between the adjacent turns of the conductor line of the winding portion 101b being changed through the pressing member. The larger the distance between the winding portion 101b and the structure in close proximity to the winding portion 101b, the smaller the change in the parasitic capacitance. In the present embodiment, the minimum distance z1 between the reference surface BL of the base 28 and the winding portion 101b of the coil 101 is set such that the change of the electrical characteristics of the inductor from the original characteristics (design specifications) is within the permissible range.

As a result, it is possible to fix the inductor 100 to the cover member 4 of the valve timing control device without deteriorating the electrical characteristics of the inductor 100 such as the self-resonance frequency and impedance. As a result, it is possible to provide a noise filter of a vehicle-mounted device which is of high noise filtering effect and which is highly resistant to vibration, a shock, etc. applied to the vehicle body and the vehicle-mounted device.

Further, in the present embodiment, the coil 101 is not covered with molding resin, so that the heat radiation property is improved as compared with the case where the coil is covered with molding resin.
(2) Both end portions of the magnetic body 103 are fit-engaged with the pair of support portions 105A and 105B. Since fixation of the magnetic body 103 in position is attainable with a simple construction, a satisfactory assembly property is provided.
(3) Both end portions of the winding portion 101b arranged between the pair of support portions 105 are bonded to both end portions of the magnetic body 103 by the adhesive 106. As a result, it is possible to achieve an improvement in terms of vibration resistance and shock resistance as compared with the case where no adhesive 106 is used.
(4) Since the support portions 105 and the magnetic body 103 are bonded to each other by the adhesive, it is possible to achieve an improvement in terms of vibration resistance and shock resistance as compared with the case where no adhesive 106 is used.
(5) In the coil 101, the leader lines 101x and 101y extending from both ends of the winding portion 101b arranged between the pair of support portions 105 are fixed to the bus bars 108a and 108b. As a result, the coil 101 is fixed to the pair of bus bar support bases 109a and 109b protruding from the cover member 4 via the bus bar 108a and 108b, and the magnetic body 103 is supported by the coil 101. As a result, it is possible to achieve an improvement in terms of vibration resistance and shock resistance as compared with the case where the magnetic body 103 is not supported via the coil 101.

### Second Embodiment

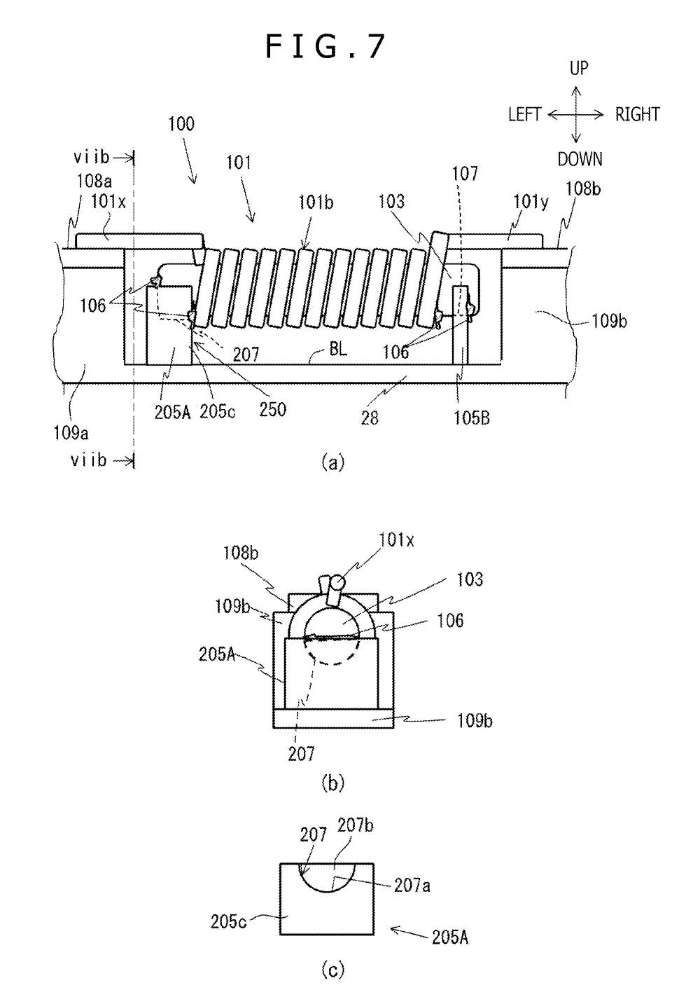

The noise filter of a vehicle-mounted device according to the second embodiment will be described with reference to FIG. 7. In the drawing, the portions that are the same as or equivalent to those of the first embodiment are indicated by the same reference characters, and the description will center on the differences. In the structure of the first embodiment, the curved surfaces 107 of the support portions 105 and the outer peripheral side surface of the magnetic body 103 are fit-engaged with each other, and the magnetic body 103 is supported by the support portions 105. In contrast, in the second embodiment, not only the outer peripheral side surface of the magnetic body 103 but also one end surface of the magnetic body 103 is supported by a support portion 205A.

FIG. 7(a) is a schematic side view of a retaining structure for the inductor 100 according to the second embodiment, and FIG. 7(b) is a schematic sectional view taken along line viib-viib of FIG. 7(a). FIG. 7(c) is a diagram illustrating the support portion 205A of FIG. 7(b) viewed from the side opposite that of FIG. 7(b). A support device 250 according to the second embodiment differs from the support device 150 of the first embodiment in that there is provided the support portion 205A instead of the support portion 105A of the first embodiment. Otherwise, they are of the same construction. The support portion 205A is provided with a fit-engagement recess 207 to be fit-engaged with one end portion of the magnetic body 103.

The fit-engagement recess 207 has a curved surface 207a to be fit-engaged with the outer peripheral side surface of the magnetic body 103, and a semi-circular flat surface 207b abutting the end surface in the axial direction of the magnetic body 103. The left end portion of the magnetic body 103 is fit-engaged with the fit-engagement recess 207 of the support portion 205A, and the outer peripheral side surface at the left end portion of the magnetic body 103 and the end surface in the axial direction thereof are covered with the support portion 205A.

The adhesive 106 is applied beforehand to the curved surface 207a and the flat surface 207b of the fit-engagement recess 207, and the left end portion of the magnetic body 103 is fit-engaged with the fit-engagement recess 207, whereby the fit-engagement recess 207 of the support portion 205A and the left end portion of the magnetic body 103 are bonded to each other by the adhesive 106.

An end surface 205c on the winding portion 101b side of the support portion 205A abuts the left end of the winding portion 101b via the adhesive 106. One end in the axial direction of the winding portion 101b is fixed to the support portion 205A, whereby it is possible to more firmly fix the magnetic body 103 in position. The change in the electrical characteristics attributable to the abutting of the end surface of the winding portion 101b on the support portion 205A is small.

In addition to the effects of the first embodiment, the second embodiment described above provides the following effects:
(6) At least one end of both ends of the winding portion 101b axially abuts one support portion 205A of the pair of support portions 205A and 105B constituting the support device 250. As a result, it is possible to further enhance the effect of regulating the movement in the axial direction of the magnetic body 103.
(7) At least one end of both ends of the magnetic body 103 axially abuts one support portion 205A of the pair of support portions 205A and 105A constituting the support device 250. As a result, as in the above (6), it is possible to further enhance the effect of regulating the movement in the axial direction of the magnetic body 103.
(8) In addition to the outer peripheral side surface of the magnetic body 103, the axial end surface of the magnetic body 103 is brought into contact with the support portion 205A, so that it is possible to augment the contact area between the support portion 205A and the magnetic body 103 than in the first embodiment. As a result, it is possible to further enhance the fixation force by the fit-engagement and bonding between the support portion 205A and the magnetic body 103.

### Third Embodiment

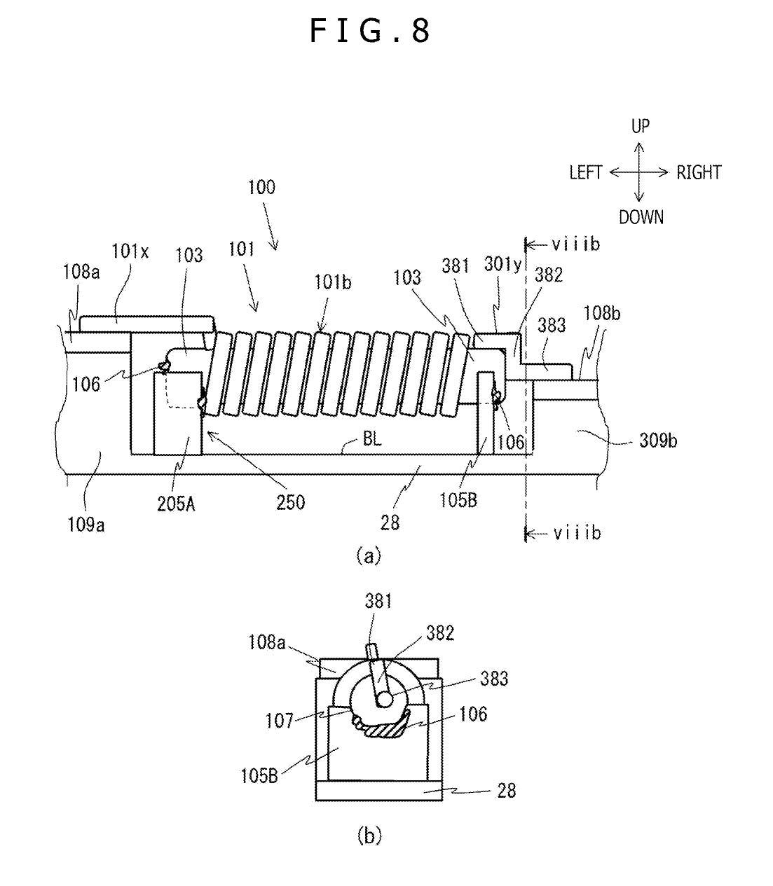

The noise filter of a vehicle-mounted device according to the third embodiment will be described with reference to FIG. 8. In the drawing, the components that are the same as or equivalent to those of the second embodiment are indicated by the same reference characters, and the description will center on the differences. FIG. 8(a) is a schematic side view of a retaining structure for the inductor 100 according to the third embodiment, and FIG. 8(b) is a schematic sectional view taken along line viiib-viiib of FIG. 8(a).

In the third embodiment, the configuration of a leader line 301y of the coil 101 is different from the configuration of the leader line 101y of the second embodiment. Otherwise, the two embodiments are of the same construction. The leader line 301y constituting the right end portion of the coil 101 constrains the right end portion of the magnetic body 103. The leader line 301y is equipped with a magnetic body abutment portion 381 abutting the upper portion of the magnetic body 103, an end surface support portion 382 bent by 90 degrees from the end portion of the magnetic body abutment portion 381 and extending toward the reference surface BL of the base 28, an a bus bar connection portion 383 bent by 90 degrees from the end portion of the end surface support portion 382 and extending toward the bus bar 108b.

The bus bar 108b is fixed to a bus bar support base 309b smaller in height as compared with that of the second embodiment. The bus bar connection portion 383 is connected to the bus bar 108b through welding.

The end surface support portion 382 abuts the right end surface of the magnetic body 103, and urges the magnetic body 103 to the left by the elastic force of the conductor line. As a result, the left end surface of the magnetic body 103 is pressed against the above-mentioned flat surface 207b of the support portion 205A. That is, the magnetic body 103 is held between the flat surface 207b of the support portion 205A and the end surface support portion 382 of the leader line 301y.

In addition to the effects that are the same as those of the second embodiment, the third embodiment provides the following effect:
(9) Both end surfaces in the axial direction of the magnetic body 103 are held between one end of the coil 101 (the right end as seen in the drawing) and the support portion 205A of the pair of support portions 205A and 105B which is arranged on the side opposite the above-mentioned one end of the coil 101. As a result, as compared with the second embodiment, it is possible to more strongly regulate movement in the axial direction.

The following modifications are included in the scope of the present invention. It is also possible to combine one or a plurality of the modifications with the above-described embodiments.

### (Modification 1)

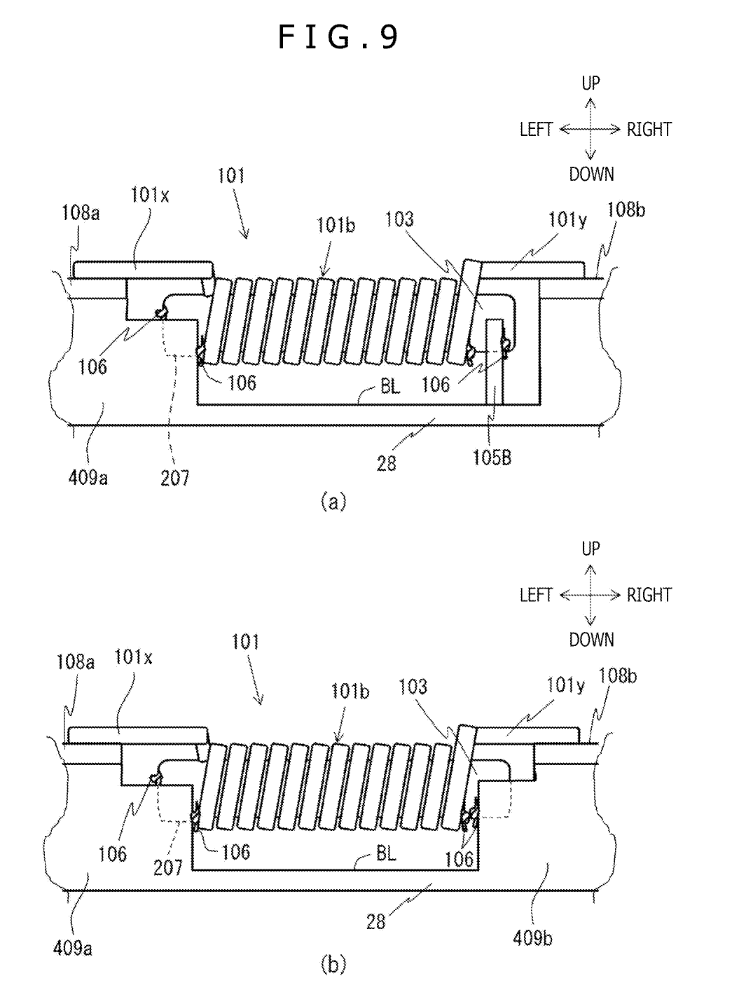

While in the second embodiment described above the support portion 205A and the bus bar support base 109a each protrude upwardly from the reference surface BL of the base 28, that is, the support portion 205A and the bus bar support base 109a protrude from the cover member 4 as separate components, this should not be construed restrictively. As shown, for example, in FIG. 9(a), there may be provided a support body 409a formed by integrating the support portion 205A and the bus bar support base 109a. That is, the support body 409a serves the function of supporting the bus bar 108a and the function of supporting the magnetic body 103. As compared with the rectangular flat-plate-like support portion 205A having a relatively small thickness, the support body 409a has a relatively high bending rigidity, so that it can retain the inductor 100 in a more stable manner.

### (Modification 2)

In the second embodiment described above there is provided the support portion 205A covering one end surface of both end surfaces in the axial direction of the magnetic body 103, this should not be construed restrictively. Both end surfaces of the magnetic body 103 may be supported by support portions. That is, the magnetic body 103 may be held between a pair of support portions. This makes it possible to regulate the movement in the axial direction of the magnetic body 103 more effectively as compared with the second embodiment. Further, as shown in FIG. 9(b), as in the above modification 1, the pair of support portions supporting both end portions of the magnetic body 103 may be integrated with the pair of bus bar support bases to form a pair of support bodies 409a and 409b.

### (Modification 3)

The retaining structure (See FIG. 8) for the magnetic body 103 due to the leader line 301y of the coil 101 according to the third embodiment may be applied to the structures of modification 1 (See FIG. 9(a)) and modification 2 (See FIG. 9(b)) described above. Further, the leader line 101x (the left end portion of the coil 101 as seen in the drawing) of the coil 101 according to the third embodiment may be formed in the same structure as the leader line 301y (the right end portion of the coil 101 as seen in the drawing).

### (Modification 4)

While in the embodiments described above a pair of support portions 105A or 205A and 105B protrude from the cover member 4, supporting the magnetic body 103 from the reference surface BL side of the cover member 4, this should not be construed restrictively. For example, a pair of support portions may be provided in the axial direction of the magnetic body 103, and the magnetic body 103 may be supported so as to be held from both axial sides of the magnetic body 103. The magnetic body 103 may be supported from the side opposite the reference surface BL side of the cover member 4. For example, the support plate of the bus bar support base 109a (the fixing portion of the bus bar 108a) shown in FIG. 5 may be extended to the right, and bent by 90 degrees toward the magnetic body 103 from the right end portion of the support plate, thus providing a support portion supporting the magnetic body 103 from the upper side.

### (Modification 5)

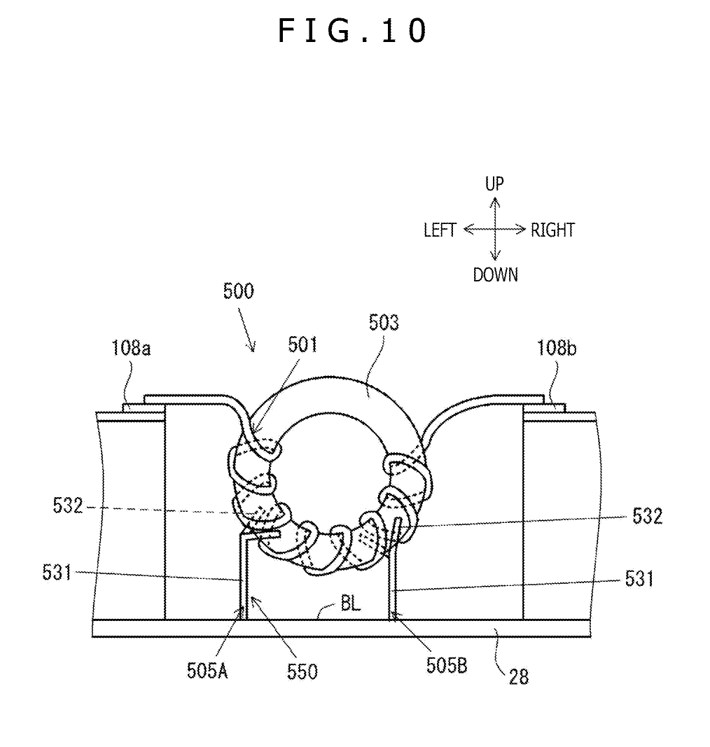

While in connection with the above-described embodiments there has been described an inductor equipped with a linear bar-like magnetic body, and a solenoid type coil 101 formed by spirally winding a conductor line around the magnetic body 103, the construction of the inductor is not restricted thereto. For example, as shown in FIG. 10, an inductor 500 equipped with an annular magnetic body 503 and a toroidal type coil 501 formed by spirally winding a conductor line around the magnetic body 503 may be adopted as the noise filter. In this case, a pair of support portions 505A and 505B constituting a support device 550 are arranged such that they do not interfere with the coil 501. The pair of support portions 505A and 505B may be equipped, for example, with a rectangular flat-plate-like base portion 531 and a U-shaped curved portion 532 forked from the upper end of the base portion 531.

### (Modification 6)

While in the above-described embodiments the adhesive 106 is employed, this should not be construed restrictively. The adhesive 106 may be omitted in the case where the inductor can be firmly fixed in position by forcing the magnetic body 103 into the position between the support portions 105A or 205A and 105B, or in the case where, as shown in FIG. 8, the inductor can be firmly fixed in position by holding the magnetic body 103 between the right end portion of the coil 101 and the support portion 205A.

### (Modification 7)

While in the embodiments described above the support devices 150 and 250 are each formed by a pair of support portions, this should not be construed restrictively. The support device may be formed by three or more support portions. For example, a region where no winding portion 101b is arranged may be provided at the middle portion of the bar-like magnetic body 103, and three portions made up of one end portion of the magnetic body 103, the other end portion of the magnetic body 103, and the middle portion of the magnetic body 103 may be supported by three support portions. The support device may be formed by one support portion. For example, a sufficient contact area to be brought into contact with the support portion 103 may be secured at the middle portion of the magnetic body 103, supporting solely the middle portion of the magnetic body 103 by one support portion. One support portion may be forked, and both end portions of the magnetic body 103 may be supported by the forked portion.

### (Modification 8)

While in the above-described embodiments a valve timing control device constitutes the vehicle-mounted device, this should not be construed restrictively. The present invention is applicable to various vehicle-mounted devices. For example, the present invention is applicable to the noise filter (inductor) of a vehicle-mounted device such as an electronic stability control (ESC) or an antilock braking system (ABS).

The various embodiments and modifications described above should not be construed restrictively. Other modes available within the technical scope of the present invention are also included in the scope of the present invention.

The disclosure of the following priority basic application is to be incorporated herein as a cited reference:

Japanese Patent Application No. 2015-186935 (filed on Sep. 24, 2015).

### DESCRIPTION OF REFERENCE CHARACTERS

1: Timing sprocket
1a: Sprocket main body
1b: Gear portion
1c: Bolt insertion hole
2: Cam shaft
2a: Flange
3: Phase change mechanism
4: Cover member
5: Motor housing
5: Motor housing
5a: Housing main body
5b: Partition wall
5c: Shaft portion insertion hole
5d: Extension portion
6: Forming portion
6a: Female screw hole
7: Bolt
8: Electric motor
9: Driven member
9a: Fixed end portion
9b: Cylindrical portion
9c: Through-hole
9d: Insertion hole
10: Cam bolt
10a: Head portion
10b: Shaft portion
11: Sealing plate
13: Motor output shaft
13a: Large diameter portion
13b: Small diameter portion
14: Permanent magnet
16: Stator
17: Core rotor
18: Coil
19: Inner teeth forming portion
19a: Inner teeth
20: Annular member
21: Retaining plate
21a: Inner peripheral portion
21b: Stopper protrusion
21d: Bolt insertion hole
22: Resin plate
23a: Resin holder
24a, 24b: Coil spring
25a: Motor brush
26a, 26b: Slip ring
28: Base
28c: Flange
28d: Boss portion
29: Covering member
30a, 30b: Opening
31a, 31b: Feeder brush
32a, 32b: Torsion spring
33: Connector portion
34: Connector portion
37: Roller bearing
38: Needle bearing
39: Eccentric shaft portion
41: Retainer
41a: Tubular distal end portion
43: Large diameter ball bearing
43a: Outer ring
43b: Inner ring
43c: Ball
47: Medium diameter ball bearing
48: Roller
49: Chain cover
49a: Female screw hole
55: Plug member
71: Commutator
90 Noise filter
100: Inductor
101: Coil
101b: Winding portion
101x: Leader line
101y: Leader line
103: Magnetic body
105: Support portion
106: Adhesive
107: Curved surface
108a, 108b: Bus bar
109a, 109b: Bus bar support base
120: Engine control unit
150: Support device
205A: Support portion
205c: End surface
207: Fit-engagement recess
207a: Curved surface
207b: Flat surface
250: Support device
301y: Leader line
309b: Bus bar support base
381: Magnetic body abutment portion
382: End surface support portion
383: Bus bar connection portion
409a: Support body
500: Inductor
501: Coil
503: Magnetic body
505A, 505B: Support portion
531: Base portion
532: Curved portion
550: Support device

1. A noise filter of a vehicle-mounted device, comprising:
a support device provided on a casing of the vehicle-mounted device;
a magnetic body supported by the support device; and
a coil having a winding portion wound around the magnetic body, wherein
the support device supports the magnetic body such that an outer peripheral side surface of the winding portion is situated at a position spaced away from the casing.

2. The noise filter of a vehicle-mounted device according to claim 1, wherein
the coil has leader lines each extending from respective ends of the winding portion and fixed to respective parts of the casing.

3. The noise filter of a vehicle-mounted device according to claim 1, wherein
at least one end of the ends of the winding portion abuts the support device.

4. The noise filter of a vehicle-mounted device according to claim 1, wherein
the support device is equipped with two support portions each to be fit-engaged with respective end portions of the magnetic body.

5. The noise filter of a vehicle-mounted device according to claim 1, wherein:
the support device is equipped with a support portion arranged on a side opposite one end of the coil; and
the magnetic body is held between the support portion arranged on the side opposite one end of the coil and one end of the coil.

6. The noise filter of a vehicle-mounted device according to claim 1, wherein:
the magnetic body is a linear bar-like member; and
the coil is a solenoid type coil spirally wound around the magnetic body.

7. The noise filter of a vehicle-mounted device according to claim 1, wherein:
the magnetic body is of an annular configuration; and
the coil is a toroidal type coil spirally wound around the magnetic body.

8. A vehicle-mounted device equipped with the noise filter of a vehicle-mounted device as claimed in claim 1.
